(19) United States
(12) Patent Application Publication
(10) Pub. No.: US 2007/0207266 A1
(43) Pub. Date: Sep. 6, 2007

(54) Method and apparatus for coating particulates utilizing physical vapor deposition

(76) Inventor: Harald Kurt Lemke, Pittsburgh, PA (US)

Correspondence Address: KENNAMETAL INC., P.O. BOX 231, 1600 TECHNOLOGY WAY, LATROBE, PA, 15650, US

(21) Appl. No.: 11/706,767

(22) Filed: Feb. 15, 2007

Related U.S. Application Data
(60) Provisional application No. 60/773,708, filed on Feb. 15, 2006.

(51) Int. Cl. B05D 7/00; C23C 16/00

(52) U.S. Cl. 427/212; 118/726

(57) ABSTRACT

Physical vapor deposition techniques are used to coat fine particulates suspended in a fluidization gas. In one embodiment, an electron beam is directed toward a target comprising a coating material to generate a vapor of the material which is subjected to a flow of carrier gas. The resultant directional physical vapor deposition cloud is introduced into a fluidized bed chamber which contains fine powder particulates to be coated suspended in the fluidization gas. As the directional vapor cloud passes through the fluidized bed, the suspended particulates are coated with the coating material. The fluidized bed may comprise a recirculating or non-recirculating fluidized bed. The system may be used to produce substantially unagglomerated fine powders having many different types of coatings.

### CROSS-REFERENCE TO RELATED APPLICATION

This application claims the benefit of U.S. Provisional Application No. 60/773,708 filed Feb. 15, 2006, which is incorporated herein by reference.

### FIELD OF THE INVENTION

The present invention relates to systems for coating particulates, and more particularly relates to the use of physical vapor deposition to coat fine particulates.

### BACKGROUND INFORMATION

Physical vapor deposition (PVD) is a commonly used method to coat structures with high performance coatings. PVD processes are atomic-scale deposition processes in which material is vaporized from a solid or liquid source in the form of atoms or molecules which are transported in the form of a vapor through a vacuum or low pressure gaseous atmosphere (or plasma) to the substrate where it condenses. PVD processes can be used to deposit films of elements and alloys, as well as compounds using reactive deposition processes, e.g., by forming compounds via the reaction of depositing material with the gas environment.

For example, cutting tools and turbine blades are coated with a variety of PVD coatings to improve their respective performances. As known in the art, the artifact to be coated is placed via a holder in a vacuum chamber and the surface of the artifact to be coated is exposed to the vaporized coating material. The coating is formed via the deposition of the vaporized coating material onto the surface of the artifact.

PVD coatings that are deposited on the surface of particulates (powders, fibers, whiskers, nanotubes, flakes, etc.) are less common. One reason for this is the increased difficulty to coat such particulate surfaces with a line-of-sight coating process like PVD. To PVD-coat particulates, it is necessary that the vaporized coating material has free access to the surface area of the particulates during the coating step. Due to the increased cohesion forces that act among finer particulates, the access to the overall particulate surface of a particulate bed is more restricted as the particulates become finer. The strong cohesion forces that act among very fine particulates such as Gelhard class C particulates or nano-sized particulates renders the PVD coating of such particulate beds particularly difficult.

One commonly practiced approach to increase access to the surface area of the particulates is to vibrate the particulates. Common devices to do so are tumbling mixers or magnetically or acoustically assisted stirrers. Some of these devices are outlined in Unit Operations of Chemical Engineering, McCabe, Smith and Harriott; 5.Edition; 1993.

Sidrabe (http://www.sidrabe.com/powders.htm), Takeshima U.S. Pat. No. 4,940,523 and Carlotto International Application No. WO 2006/083725 propose to use such devices in combination with PVD coating methods to coat powders.

Sidrabe uses a rotating drum that is inserted in an evacuated drum to elevate the powder mechanically. The powder is coated while it is falling down from the top of the drum by passing the powder on its decline through a vapor cloud of the coating material. Once the powder arrives at the bottom of the drum, the powder is either removed or re-elevated via the rotating drum for a subsequent coating step.

Takeshima points out some of the deficiencies that are associated with Sidrabe's set up, such as the difficulty in uniformly coating heavy particles and the adherence of light particles to the magnetron. However, Takeshima's approach to coat the powder while the powders are agitated in a rotating drum also has problems since the particle momentum that is generated in such a rotating drum is insufficient to generate freely suspended particulates. As evidenced by the high powder bed densities of the sliding particulate beds in such rotating drums, access of the vaporized coating material remains restricted to the fraction of the particulate surfaces that are in the line-of-sight of the coating vapor source.

Carlotto proposes to use a vibrating beaker or other mechanical means to increase access to the surface of the particulates. However, these approaches suffer from similar deficiencies as the approach suggested by Takeshima. In addition, the methods described by Carlotto are inefficient since the disclosed set-ups only utilize a small fraction of the vaporized coating material to coat the powders while the majority of the vaporized coating material is deposited on the other internal surfaces.

The approach of using a recirculating fluidized bed as a means to increase the access of vaporized coating materials to the surface of particulates and to coat such particulates with chemical vapor deposition (CVD) coatings has been suggested by Sherman in U.S. Pat. No. 5,876,793, which is incorporated herein by reference. A typical configuration of the applied circulating fluidized bed includes a stand pipe, means for introducing solid particles into the standpipe, a sufficient upward flow of fluid such as a gas to cause substantial entrainment of particles from the top of a riser section, and means for capturing most of the solid particles with a cyclone or the like, and returning them continuously to the standpipe.

In such a CVD process, particle coatings are formed by the deposition of atoms or molecules onto the particulate surface via the reduction or decomposition of a chemical vapor precursor species which is added to the fluidizing gas, in contrast to typical PVD coatings, where the final composition of the coating material is evaporated and condensed on the particulate surface. However, the addition of a chemical vapor precursor species is associated with problems such as limited availability or toxicity of such precursors, and the tendency of such precursors to contaminate the coating or limit the throughput of the process.

Therefore, despite these known processes, a need exists for the efficient production of composite particulates that do not require the use of undesirable coating precursors.

### SUMMARY OF THE INVENTION

The present invention provides a method and an apparatus for efficiently applying coatings to powder surfaces using physical vapor deposition (PVD). More specifically, this invention utilizes circulating or non-recirculating fluidized beds to deposit PVD coatings. By introducing external gas into the fluidized bed, the particulates become individually suspended in the gas and thereby enable the physically vaporized coating material to coat the particulates more efficiently.

In one embodiment, directed vapor deposition (DVD) techniques may be used to direct a vapor cloud of the coating material toward the powder particles to physically deposit the vapor on the particulates. The vapor cloud of the coating material is introduced into a fluidized bed containing the particulates to be coated. For example, a recirculating fluidized bed may be used to coat Geldart Class C cohesive powders to modify their surfaces by providing a coating on each particle. Since PVD involves an atom-by-atom deposition from the vapor phase rather than decomposition or reduction of a precursor compound, impurity levels of the coatings are very low, e.g., less than 1 or 2% or even less than 0.1%, and densities of the coatings are very high, e.g., at least 95 or 99% or 99.9%. The fully or partially coated powders may be used for various applications such as fillers, coatings and consolidated structural materials.

An embodiment of the present invention provides a method that enables the coating of particulates by combining directed vapor deposition (DVD) techniques with equipment used to fluidize particulates, such as fluidized beds, recirculating fluidized beds and inverted cone fluidized beds. The method allows for the low-cost production of a wide variety of novel composite particulates such as powders, fibers, unwoven fibers, chopped fibers, milled fibers, whiskers, nanosized materials, dendrimers, pigments and/or amorphous materials and the like.

An aspect of the present invention is to provide a method of coating particulates by physical vapor deposition. The method comprises generating a vapor containing a coating material in a vacuum, suspending the particulates to be coated in a fluidization gas, and physically depositing the vapor on the suspended particulates in the fluidization gas to at least partially coat the particulates with the coating material.

Another aspect of the present invention is to provide an apparatus for coating particulates comprising means for generating a vapor containing a coating material in a vacuum, means for suspending the particulates to be coated in a fluidization gas, and means for physically depositing the vapor on the suspended particulates in the fluidization gas to at least partially coat the particulates with the coating material.

A further aspect of the present invention is to provide an apparatus for coating particulates comprising a source of vaporized coating material, and a fluidized bed containing the particulates to be coated suspended in a fluidization gas, wherein the vaporized coating material is physically deposited on the suspended particulates in the fluidized bed.

These and other aspects of the present invention will be more apparent from the following description.

### BRIEF DESCRIPTION OF THE DRAWINGS

FIG. 1 is a flow chart illustrating a DVD process for coating fine particles in accordance with an embodiment of the present invention.

FIG. 2 is a flow chart illustrating a DVD process for coating fine particles in accordance with another embodiment of the present invention.

FIG. 3 is a flow chart illustrating a DVD process for coating fine particles in accordance with a further embodiment of the present invention.

FIG. 4 schematically illustrates a PVD/fluidized bed system in accordance with an embodiment of the present invention.

FIG. 5 schematically illustrates another PVD/fluidized bed system in accordance with an embodiment of the present invention.

FIG. 6 is a partially schematic longitudinal section view of an inverted cone used as a fluidized bed for DVD in accordance with an embodiment of the present invention.

FIG. 7 is a partially schematic longitudinal section view of a tumbling bed reactor used as a fluidized bed for DVD in accordance with another embodiment of the invention.

FIG. 8 illustrates a particulate having a PVD coating layer in accordance with an embodiment of the present invention.

FIG. 9 illustrates a particulate having two PVD coating layers in accordance with another embodiment of the present invention.

FIG. 10 shows uncoated and nickel-coated glass beads.

FIGS. 11 and 12 show microscopic images of coated glass beads made by DVD processes of the present invention.

FIG. 13 shows a copper coating on tungsten carbide powders produced in accordance with an embodiment of the present invention.

FIG. 14 is a photomicrograph of tungsten carbide particulates coated with cobalt produced by a DVD coating process of the present invention, and a corresponding x-ray diffraction spectrum.

FIG. 15 is the same photomicrograph of tungsten carbide particulates coated with cobalt as shown in FIG. 14, but with an x-ray diffraction spectrum taken from a different location.

FIG. 16 is a photomicrograph of tungsten carbide particulates coated with cobalt produced by a DVD coating process of the present invention, and a corresponding x-ray diffraction spectrum.

FIG. 17 is a photomicrograph of tungsten carbide particulates coated with cobalt produced by a DVD coating process of the present invention.

FIG. 18 is a photomicrograph of cobalt-coated tungsten carbide particulates similar to those shown in FIG. 17 which were mounted and polished to show the cross section of the tungsten carbide particulates and cobalt coatings.

FIG. 19 is a photomicrograph of tungsten carbide particulates coated with nickel produced by a DVD coating process of the present invention, and a corresponding x-ray diffraction spectrum.

FIG. 20 is a photomicrograph of tungsten carbide particulates coated with nickel produced by a DVD coating process of the present invention, and a corresponding x-ray diffraction spectrum.

FIG. 21 is a high resolution photomicrograph of a tungsten carbide particulate coated with nickel produced by a DVD coating process of the present invention.

FIG. 22 is a photomicrograph of tungsten carbide particulates coated with a first nickel coating and a second bronze coating produced by a DVD coating process of the present invention and a corresponding x-ray diffraction spectrum.

### DETAILED DESCRIPTION

In accordance with the present invention, physical vapor deposition (PVD) techniques are used for coating particulates that are suspended in a fluidizing bed by a fluidization gas. The physical vapor deposition may be directed (DVD) or non-directed. In one embodiment, combining fluidized beds with direct vapor deposition provides significant advantages in the way advanced materials such as composite powders or fibers are designed and manufactured. Using fluidization techniques, defined and repeatable coatings may be applied to particulates such as powders or chopped and milled fibers or whiskers on the particle-to-particle level.

Directed vapor deposition (DVD) may be used in combination with an electron beam-based evaporation technique to improve yield and/or quality of high performance thick and thin film coatings. The ability of DVD techniques to focus and direct the vapor cloud to a specified target space can enhance the deposition rates and material utilization efficiencies as well as lead to a more precise control of the coating process. Direct vapor deposition can be used to achieve the complete coating or encapsulation of fine powders, e.g., 1 nm-1 mm, with a coating material.

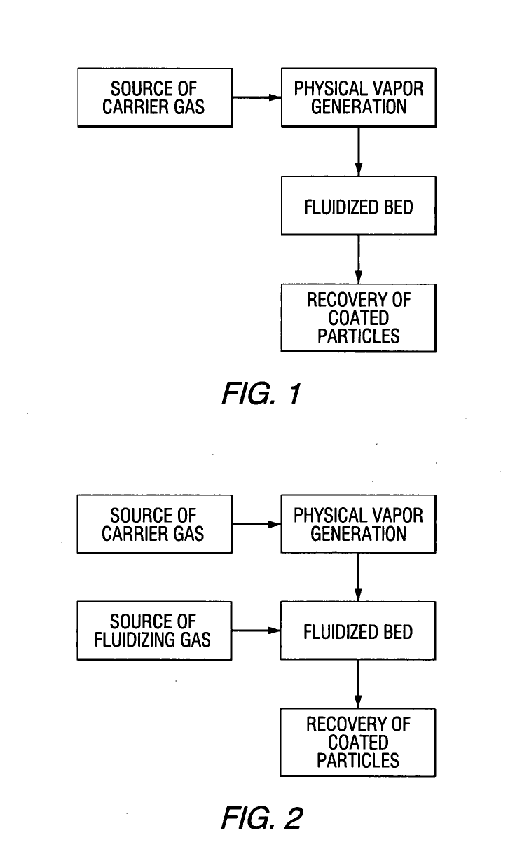

FIG. 1 illustrates a DVD process for coating fine particulates in accordance with an embodiment of the present invention. A source of carrier gas is directed into a chamber in which a physical vapor of a coating material is generated. The physical vapor may be generated by directing an electron beam toward at least one target comprising the coating material. The evaporated cloud of coating material is entrained by the carrier gas, and the mixture is introduced into a fluidized bed which contains fine particulates to be coated. In the embodiment shown in FIG. 1, the source of carrier gas is used for the dual purpose of directing the vapor cloud of coating material and fluidizing the particulates to be coated in the fluidized bed. The cloud of evaporated coating material, directed by the carrier gas, enters the fluidized bed and is physically deposited on the particulates contained in the bed.

FIG. 2 illustrates a DVD process similar to that shown in FIG. 1, except a separate source of fluidizing gas is fed to the fluidized bed. In this embodiment, one source of carrier gas is used to direct the evaporated coating material cloud, while another source of fluidizing gas is used to produce the fluidized bed.

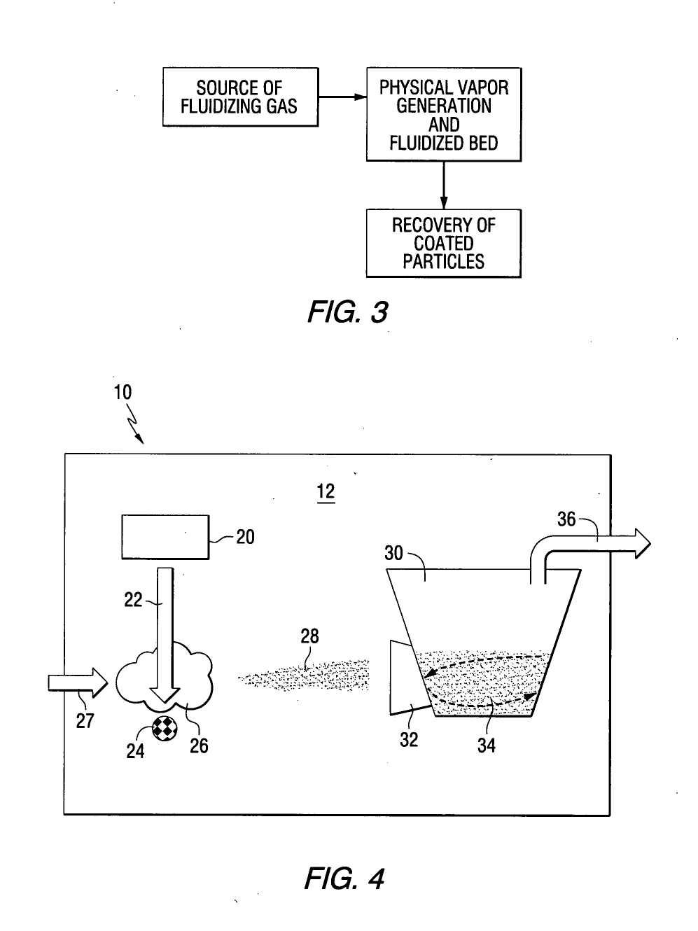

FIG. 3 illustrates a further DVD process in which a single chamber is used for physical vapor generation and as a fluidized bed. In this embodiment, a source of fluidizing gas is fed into the combined physical vapor generation and fluidized bed chamber where the evaporated coating material cloud is deposited on the fine particulates to be coated.

FIG. 4 is a partially schematic side view of a directional PVD/fluidized bed system 10 comprising a vacuum chamber 12. A physical vapor is generated inside the chamber 12 by means of a conventional electron beam source 20 which directs an electron beam 22 toward a target comprising a coating material 24. The electron beam 22 heats and vaporizes the target coating material 24 to form a vapor cloud 26 of the coating material. The coating material vapor comprises atoms and/or ions of the coating material. A carrier gas 27 is introduced into the vacuum chamber 12 where it contacts the vapor cloud 26 and forms a directed vapor 28 comprising a mixture of the coating material vapor and carrier gas. A fluidized bed 30 contained in the vacuum chamber 12 has an inlet 32 through which the directed vapor 28 travels. Particulates to be coated 34 are contained in the fluidized bed 30, where they are fluidized by the carrier gas and/or by a separate source of fluidizing gas. Inside the fluidized bed 30, the coating material vapor is physically deposited on the suspended particulates of the fluidized bed 34, providing a coating on the particles which has substantially the same composition as the target material 24. The carrier gas and/or fluidizing gas may be exhausted 36 from the fluidized bed in order to separate the gas from the coated particulates.

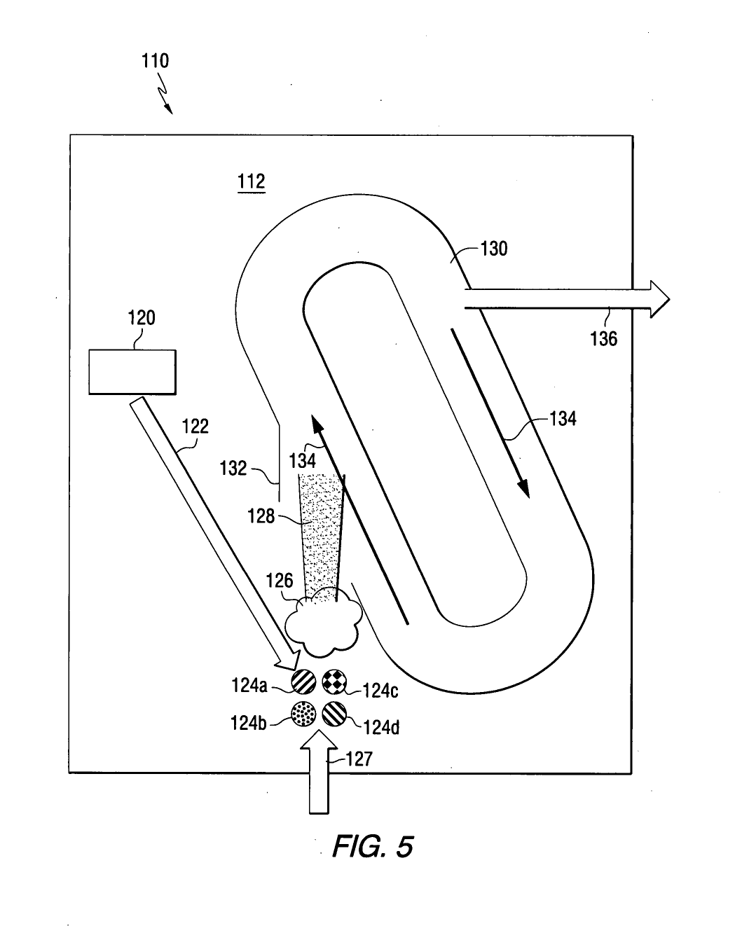

FIG. 5 is a partially schematic front view of another embodiment of a directional PVD/fluidized bed system 110 similar to that shown in FIG. 4, except multiple targets 124a-d are contained in the vacuum chamber 112. The targets 124a-d may comprise the same or different materials. For example, one target may comprise one type of elemental metal and the other target may comprise another type of elemental metal in order to form an alloy or intermetallic coating comprising the metals. A computer-controlled electron beam source 120 inside the vacuum chamber 112 generates an electron beam 122 which is selectively directed at the targets 124a-d in order to generate a vapor cloud 126 of the coating material(s). Carrier gas 127 introduced into the vacuum chamber 112 contacts the vapor cloud 126 to form a directed vapor 128 comprising a mixture of the evaporated coating material and carrier gas. The directed vapor 128 is introduced into a fluidized bed 130 via an inlet 132 where the directed vapor contacts fluidized particulates 134 suspended or flowing inside the fluidized bed 130. The carrier gas and/or fluidizing gas may be exhausted 136 from the fluidized bed 130 and vacuum chamber 112.

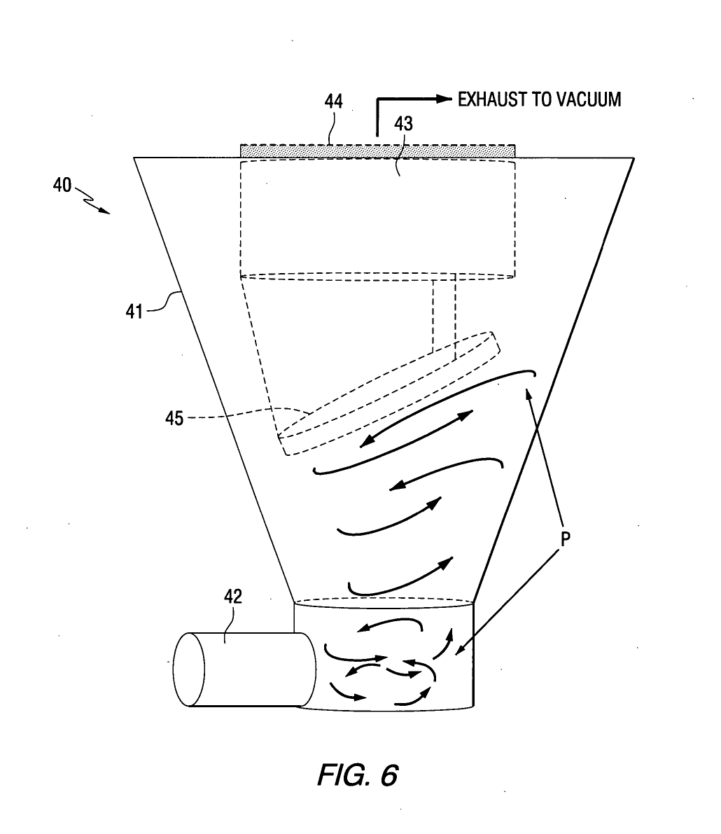

FIG. 6 is a partially schematic longitudinal section view of an inverted cyclone 40 for circulating the powders. The inverted cyclone 40 comprises a generally conical reactor vessel 41 having an inlet 42 for the metal vapor and carrier gas, shown by the solid arrows in FIG. 6, and an exhaust 43 covered with a mesh screen 44 connected to a vacuum source (not shown). A baffle 45 is suspended in the conical reactor vessel 41. The gas stream along with the vapor enters through the feed nozzle 42 at the bottom of the cyclone 40. The tangential motion of the gas stream in the cyclone 40 carries the particulates P from the bottom and keeps the rotating trajectory along the increasing diameter cone. The gas flow conditions are maintained in such a way that the inlet gas velocity should be enough to circulate the particulates P and outlet velocity should be less then their terminal/escape velocity. The cyclone 40 is designed to satisfy the criterion of getting different gas flow velocities at the inlet 42 and outlet 43 sections with the same volumetric flow rates by changing the cross-sectional surface area.

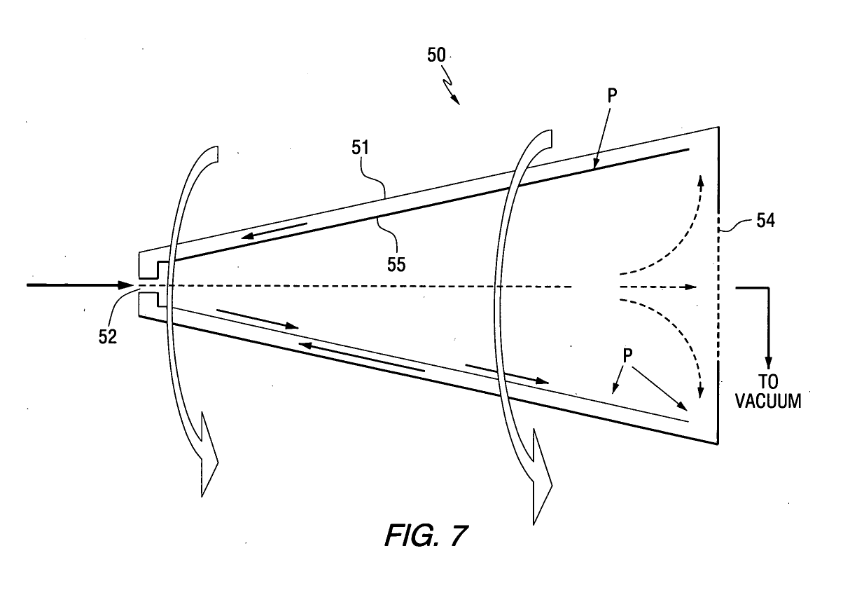

FIG. 7 is a partially schematic longitudinal section view of a tumbling bed reactor 50 used as a fluidized bed for DVD in accordance with another embodiment of the invention. As shown in FIG. 7, the fluidized bed reactor 50 has a generally cone-shaped outer wall 51 and is oriented for rotation around a horizontal axis of the cone. The narrow end of the cone includes a central inlet hole 52 through which the DVD vapor cloud is introduced into the fluidized bed. The large end of the cone comprises an outlet which is covered with a fine mesh screen 54 that permits the carrier gas to escape from the fluidized bed, but which retains most or all of the particulates inside the bed. For example, the fine mesh screen 54 may comprise 30 micron openings, or any other suitable mesh size. The components of the tumbling bed reactor 50 may be made from any suitable material such as stainless steel. A drive mechanism such as a toothed sprocket (not shown) may be used to rotate the conical fluidized bed reactor 50 around its horizontal axis at any desired rotational speed. The conical fluidized bed reactor 50 comprises a double-walled construction in which a smaller conical sleeve 55 provides a return channel between the inner wall of the outer cone 51 and the outer wall of the inner cone 55. With this arrangement, as the mixture of carrier gas and coating material vapor enters the narrow end 52 of the cone and travels toward the large open end of the cone in FIG. 7, a large portion of the carrier gas, shown by the dashed arrows in FIG. 7, exits the fluidized bed through the fine mesh screen 54, while the coated particulates P circulate back toward the narrow end of the cone between the outer 51 and inner 55 conical sleeves. Such an arrangement may be used for batch-type processing in accordance with an embodiment of the present invention.

Many different types of particulates may be coated in accordance with the present invention. For example, the particulates may comprise powders, fibers, unwoven fibers, chopped fibers, milled fibers, whiskers, nanosized materials, dendrimers, pigments and/or amorphous materials. The particulates may comprise elements, metals, metal alloys, ceramics, oxides, carbides, borides, nitrides, carbonitrides, plastics, woods and the like. For example, the particulates may comprise tungsten carbide, ductile iron, steel, stainless steel, clay, seacoal, graphite, alumina, glass, mullite and the like. Examples of some metal particulates include nickel, iron, steel, stainless steel, aluminum, tungsten and the like. Examples of oxide particulates include titania, alumina, and the like. Examples of carbide particulates include tungsten carbide, boron carbide, titanium carbide, and the like. The particulates typically have an average size of less than 10 mm, for example, from 1 nm to 1 mm. In one embodiment, the particulates have an average size of from 5 nm to 1 or 10 microns.

In one embodiment, the physically deposited coating comprises a single layer of material. In another embodiment, the physically deposited coating comprises multiple layers. The coating material may be functionally graded. The coating material may fully coat the particulates. However, in certain embodiments, the coating material may partially coat the particulates. The physically deposited coating may have a thickness of from 1 nm to 1,000 microns, for example, from 10 nm to 100 microns. In one embodiment, the physically deposited coating may have a controlled orientation.

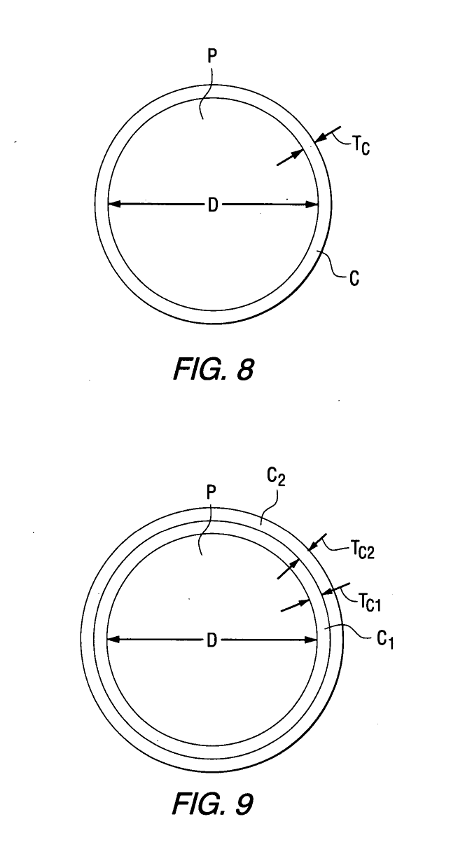

FIGS. 8 and 9 illustrate particulates with DVD coatings in accordance with embodiments of the present invention. In FIG. 8, a substrate particulate P having a diameter D has been coated with a single layer C of material deposited by physical vapor deposition. The coating C has a thickness T_{C}. In FIG. 9, a substrate particulate having a thickness D is coated with a first physical vapor deposited layer C₁ having a thickness T_{C1}, and a second physical vapor deposited layer C₂ having a thickness T_{C2}.

In accordance with embodiments of the present invention, the coating material vapor may comprise at least one substantially pure metal, metal alloy, intermetallic, ceramic, amorphous material, glass, clay and/or carbonaceous material. In accordance with an embodiment of the present invention, the fluidized particulates may be exposed to a plasma field comprising the coating material.

In one embodiment, the carrier gas is inert and may comprise, for example, He, Ar and/or Ne. In another embodiment, the carrier gas is reactive and may comprise, for example, N₂, O₂, H, Br₂ and/or B₂H₆. In a further embodiment, the carrier gas may comprise a mixture of such inert and reactive gases.

The vacuum chamber may be maintained at any suitable pressure, e.g., a pressure of from about 10⁻⁵ to 100 Torr, for example, from 10⁻⁴ to 10 or 50 Torr. In one embodiment, the vacuum chamber is maintained at a pressure below 10 Torr, for example, from 10⁻³ to 1 Torr.

Fluidizing gas may be introduced into the fluidizing bed at a velocity and orientation that effectively suspend the particulates during the coating process, e.g., from 0.01 to 100 m/s, for example, from 0.01 to 30 m/s. The deposition rate of the coating material on the particulates may be between 0.01 g/hour and 1,000 kg/hour, for example, from 1 g/hour to 1,000 kg/hour.

In one embodiment, the particulates contained in the fluidized bed may be preheated prior to introduction of the coating material vapor. For example, the particulates may be preheated above ambient temperature to temperatures up to 1,000° C. or 1,500° C., e.g., from 20° C. or 25° C. to 500° C. or 1,000° C.

DVD methods may be particularly suitable for use in accordance with the present invention. DVD allows evaporating of large amounts of the coating material(s) via e-beam bombardment at a much higher pressure (up to 10 Torr) than commonly possible (10⁻³ Torr). Also, the generated vapor cloud of the coating material does not diffuse equidirectionally from the material source (billet, rod) but rather can be focused and intentionally directed to a predefined target area. Another benefit of DVD is achieved by enclosing the vapor cloud with a carrier gas that is added to the vacuum in such a fashion that it confines and directs the generated vapor cloud into a particular direction or target space. The benefits can be utilized in combination with a fluidized bed to manufacture large amounts of particulates that are coated in a defined manner.

The ability of the DVD technology to focus and to direct the vapor cloud of the coating material to a particular target space can be exploited for coating particulates if the cloud is directing via means into an apparatus that contains a large amount of particulates. The ability to generate such directionally targeted vapor clouds, even at relatively high pressures, can be utilized to fluidize the particulates inside the apparatus due to sufficiently high kinetic energies of such high-pressure vapor clouds.

It is known that gas, routed with a certain minimum amount of kinetic energy through a pile or other aggregation of particulates will cause the fluidization of the aggregate grains. Under certain fluidization conditions, the complete disaggregation of each grain of the particulate suspension can occur. In case of such a complete disaggregation, the vapor cloud has full access to the entire surface of each grain of the particulate suspension, and can coat the surface in a defined and repeatable manner, such as partial or complete encapsulation of the particulate. Even fine cohesive particulates can be encapsulated with one or more uniform coatings at a single particle level.

A wide variety of fluidization apparatus can be employed in combination with the DVD method to manufacture coated particulates in which the coating material deposition can be controlled on a single grain level. The wide variety of fluidization apparatus may be divided into three groups: single or multiple risers; single or multiple downers; and any combination of riser(s) and downer(s). A riser is defined as an apparatus in which the carrier gas/vapor cloud gas mixture flow directs the particulate flow upward. A downer is defined an apparatus in which the carrier gas/vapor cloud gas mixture flow directs the particle flow downward.

A typical configuration of a fluidized bed operated in a riser mode includes a stand pipe, means for introducing solid particulates into the standpipe, and a sufficient upward flow of a fluidizing medium such as a gas to lift the solid particulates. The operating conditions in a riser are set such that the solid particulates coexist in a dense and dilute state or regime. The dense turbulent regime tends to break down the agglomerates and provides for required high heat and mass transfer rates. The dilute state or regime is used to deposit the vapor cloud. The high gas/solid velocities in the dilute zone promote the even deposition of the vapor cloud and thereby the even encapsulation the individual particulates with a uniform coating film or layer. Therefore, proper control of the distribution of both states in the reactor is essential to enable the encapsulation of fine powders with near-atomic level control over composition, purity and structure.

A typical downer consists of a vertical column for particle gas flow, gas-solid distributor at the top and a gas-solid separator at the bottom. The downer can be run in a recirculating mode if the passed through particulates are carried back to the top of a gas-solid distributor via a riser section by either mechanical or pneumatic means. The gas-solid distributor may consist of multiple small diameter vertical distribution tubes or nozzles to deliver the solids in the downer vertical column.

The co-current down-flow circulating fluidized bed or downer reactors may have advantages over risers due to a shorter gas-solid contact time and a more uniform gas/solid distribution due to the nature of the gas solid flow in the direction of gravity. Since solid acceleration is caused by both gravity and drag, the system can be operated at lower pressures and higher solid flux than the riser. To elaborate, a riser section is flexible to operate in both non-circulating and recirculating fluidized bed reactors. However, for fine cohesive powders such as Gelhard class C powders, the recirculating fast fluidized and turbulent fluidized bed, operated with a riser section in dense (bottom zone) and dilute regimes at the top zone, are preferred if total encapsulation of the powder is required.

While riser and downer fluizided beds are described above, any other suitable arrangement may be used, such as horizontal-flow fluidized beds which may be rotated around a horizontal axis during operation. In one embodiment, the fluidized bed reactor may comprise a recirculating fluidized bed in which the flow of gas particles in the riser section is between turbulent and fast fluidized regimes. In another embodiment, the fluidized bed reactor may comprise a non-recirculating fluidized bed in which the flow of gas particles is between minimum fluidization and turbulent fluidization regimes.

In one embodiment of the present invention, the recirculation of particulates in a fluidized bed reactor system, with the coexistence of dense and dilute regimes at controlled vacuum conditions, may be accomplished for high gas-solid mixing, heat and mass transfer, and to disaggregate the fine particulates to control the coating material deposition on a single solid level. For example, a recirculating fast fluidized and turbulent fluidized bed may be operated with a riser section in dense and dilute regimes. The dilute regime may be used for metal vapor deposition and carry out zone of solids, and the dense regime may be used to create sufficient turbulence in the gas-solid mixture. Such regimes tend to break down the agglomerates. The encapsulation of fine powders using PVD and a fluidized bed provides near-atomic level control over composition, purity and structure.

In another embodiment of the invention, a metal strip may be fed to the dilute region of the riser and the contact of electron beam or welding electric arc with metal is made at or near the center of the riser pipe producing a vapor cloud which is carried out by the gas-solid stream from the bottom of the riser. The axial and radial motion of the solids may be controlled in order to provide a layer of the metal on the surface of the powder particles and aids in continuous and complete utilization of the vapor on the powders, rather than on the riser walls. Particulate velocities in the developed flow region of the riser passing the vapor cloud may be controlled in order to build nano metal layers on a single particle level. The operating riser parameters such as gas-solid velocity, solid flux, temperatures and system pressure can all be varied, facilitating wide processing condition variation and allowing for improved control over the properties of the deposited layer.

The fluidized bed reactor may comprise a reactor similar to that disclosed in U.S. Pat. No. 5,876,793 modified to operate in a regime of dense bottom riser section and dilute section at the top at the operating pressure of about 10⁻⁴ to 10 Torr.

The present invention provides a PVD-coating method that enables the coating of particulate surfaces such as the surfaces of powders as well as chopped or milled fibers or whiskers. The method may extend the non-line-of-sight-applicability of a particular PVD technology to a DVD method for coating of particulate surfaces. While a focused, directed vapor cloud can be generated and directed to a particular target area with high kinetic energy due to the use of relatively high pressures, the kinetic energy of the focused vapor cloud can be also used to fluidize particulates to thereby coat particulates in a defined manner, e.g., if the focused vapor cloud is directed via means into the opening of an apparatus that allows for the fluidization of particulates such as powders, chopped or milled fibers or whiskers.

In accordance with an embodiment of the invention, the DVD vapor generation and DVD fluidization steps are not physically separated but conducted in the same unit. For example, the evaporization of the coating material might be conducted directly in the fluidization reactor, by placing the evaporization source such as an electron-beam and the coating material source (rod, billet) directly in the fluidization reactor.

Various experiments were carried out to demonstrate the DVD and recirculation fast fluidized bed coating method. The particulate substrates used were powders of glass beads, tungsten carbide and graphite:

| | | |
|---|---|---|
| a) | Glass Beads | |
| | Size: | 500 μm |
| | Particle density: | 2.5 g/cc |
| b) | Tungsten Carbide (WC) | |
| | Size: | d50 = 60 μm |
| | Particle density: | 16 g/cc |
| c) | Graphite | |
| | Size: | d50 = 75 μm |
| | Particle density: | 2.25 g/cc |

The coating material was nickel and/or copper. The carrier gas stream was helium.

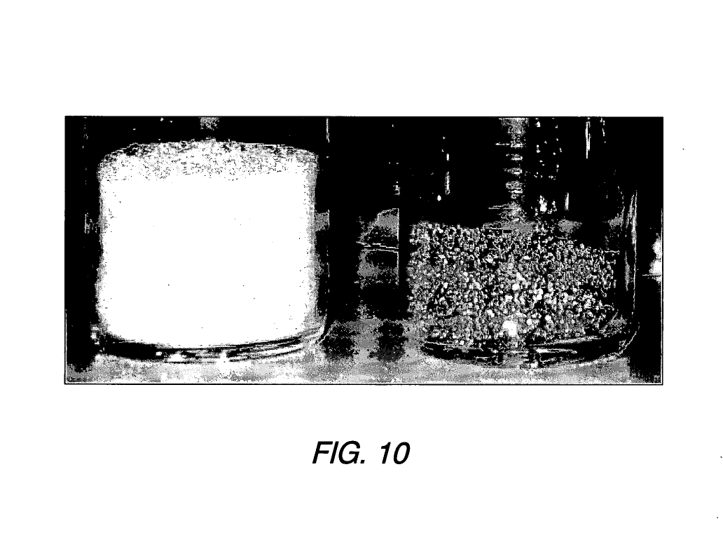

FIG. 10 shows the primary difference in terms of uncoated and nickel coated glass beads. The glass beads used were of 500 μm in size. The grey-black color on the beads clearly provides the evidence of the nickel coating on the surface of the glass beads. The flow conditions for the running the sample were as follows:

Experimental Conditions:

| | | |
|---|---|---|
| Sample Wt: | 40-45 | gm |
| Gas Flow rate: | 25-32 | l/min |
| System Pressure: | 0.5-0.9 | Torr |

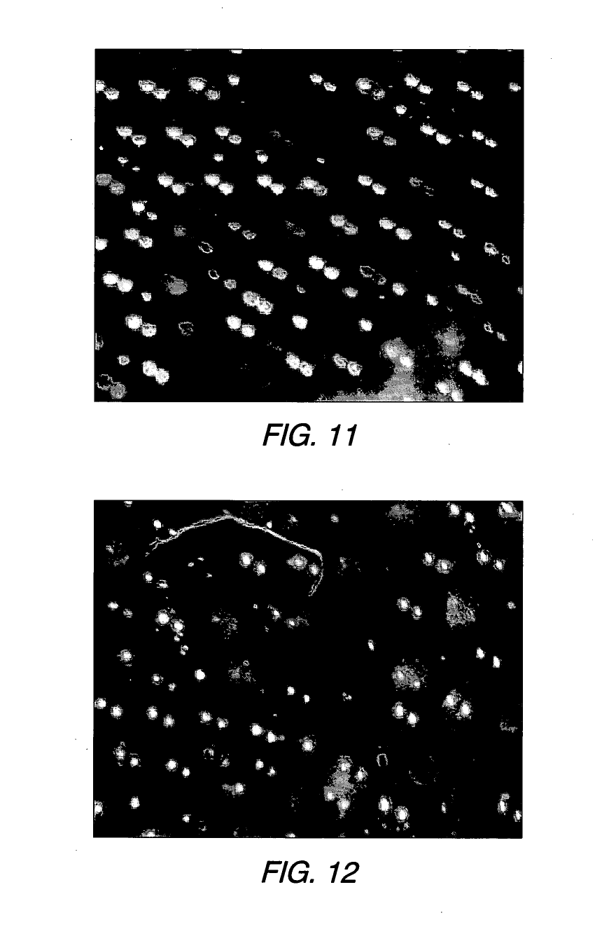

Attempts were made to coat the powders with nickel and copper coating on top of nickel coated glass beads. Adjusting the flow conditions between 25 and 32 l/min and the direction of the metal vapor with the aid of the gas nozzle direction varied the coating rates. FIG. 11 is a photomicrograph of the nickel coated glass beads. FIG. 12 is a photomicrograph of nickel coated glass beads similar to those shown in FIG. 11, which were subsequently coated with copper.

Another group of experimental trials were performed on tungsten carbide powders which were of 60 microns size coated with copper. The experimental conditions were as follows:

Experimental Conditions:

| | | |
|---|---|---|
| Sample Wt: | 50-100 | gm |
| Gas Flow rate: | 15-30 | l/min |
| System Pressure: | 0.5-1 | Torr |

The direct vapor deposition of copper on 60 μm WC powders worked well using a rotating fluidized bed.

A further group of experimental runs has made on 75 μm graphite powders coated with copper. The size and density of the powders determines the minimum fluidization velocity, rotating velocity and the escape velocity of the solids. The inlet, outlet and the cone angle of the inverted cyclone is designed in such a way that it satisfies the criterion of handling powders in the system during the run time. A screen may be used at the top of the cyclone to prevent the escape of the powders in case of losing the flow conditions. The experimental conditions used were as follows:

| | | |
|---|---|---|
| Sample Wt: | 15-20 | gm |
| Gas Flow rate: | 15-20 | l/min |
| System Pressure: | 0.3-0.6 | Torr |

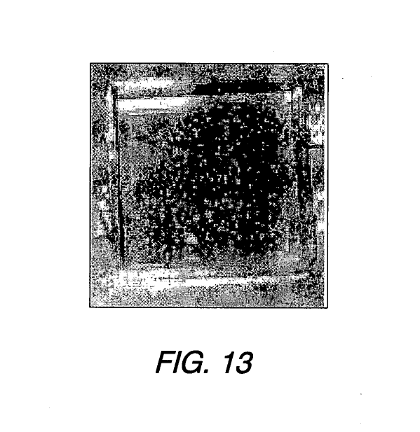

FIG. 13 is a photograph of the resultant copper-coated graphite powder.

Additional experiments were performed with tungsten carbide particles coated with either Co or Ni as listed in Table 1 below.

TABLE 1

| Sample No. | Substrate | Co (%) | Ni (%) |
|---|---|---|---|
| AWK226 | 28 micron WC powder | 0.39 | |
| AWK227 | 28 micron WC powder | 0.67 | |
| AWK228 | 109 micron WC powder | 1.73 | |
| AWK230 | 100 micron WC powder | | 0.57 |
| AWK231 | 41 micron cast carbide | | 1.12 |

In addition to the Sample Nos. listed in the table above, another run of WC particles coated with Ni was performed, corresponding to Sample No. 6.

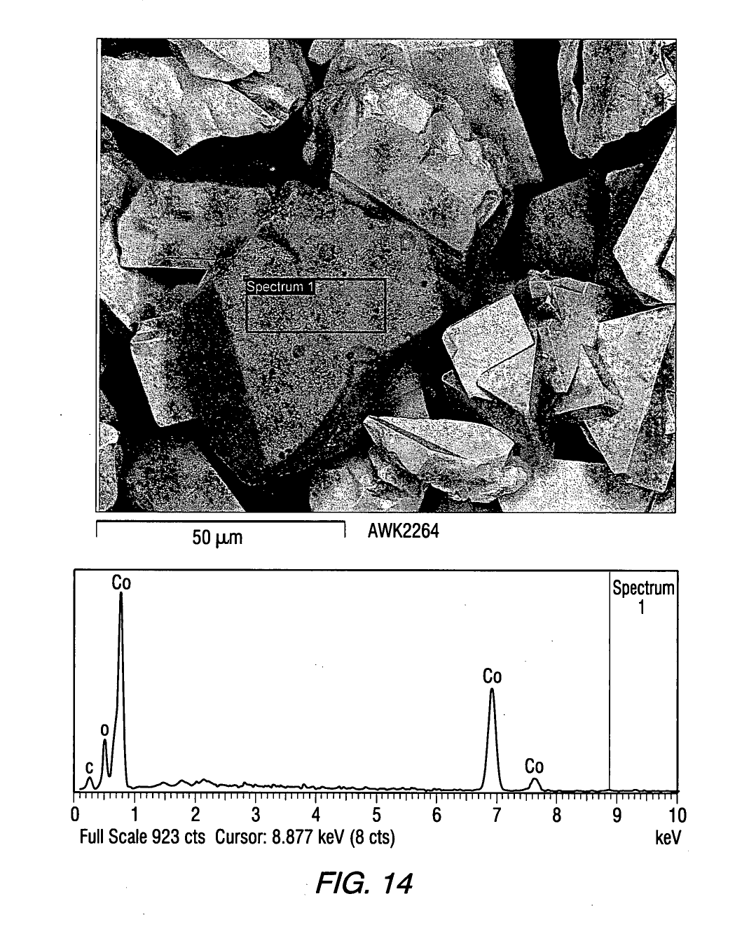

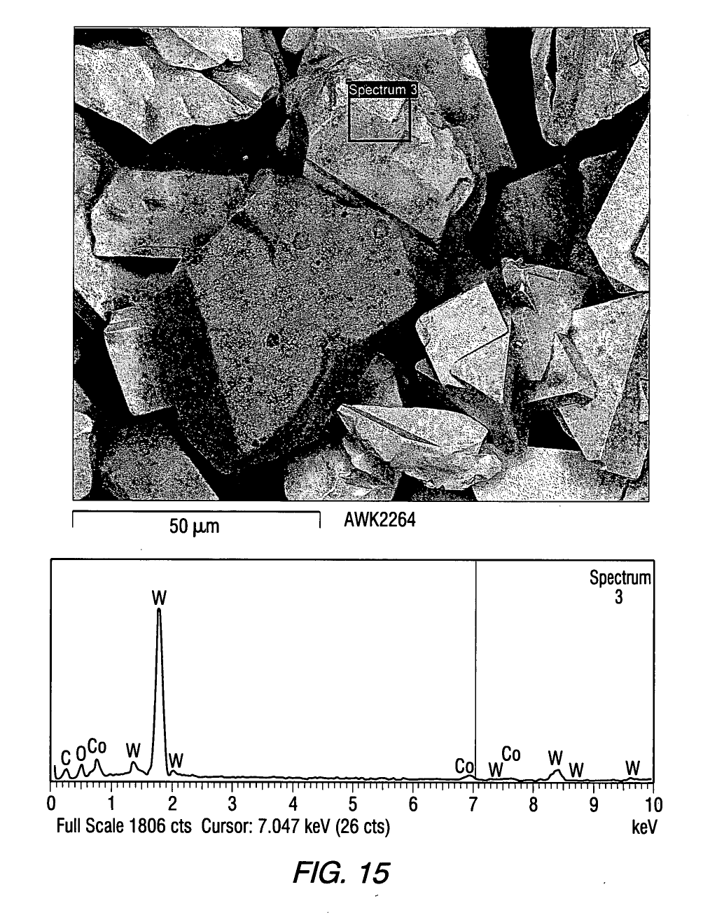

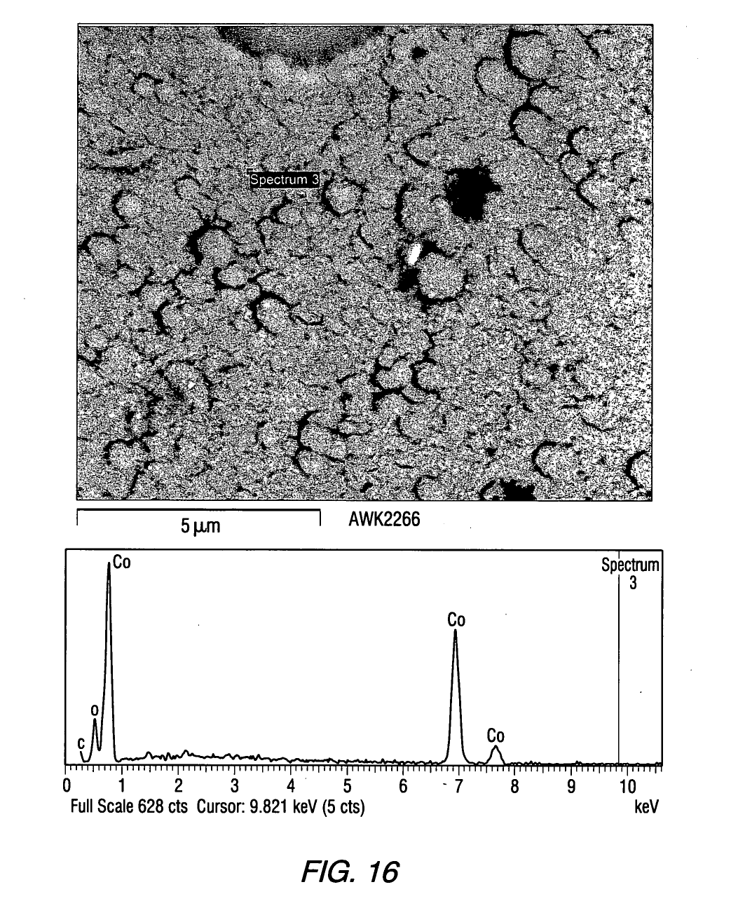

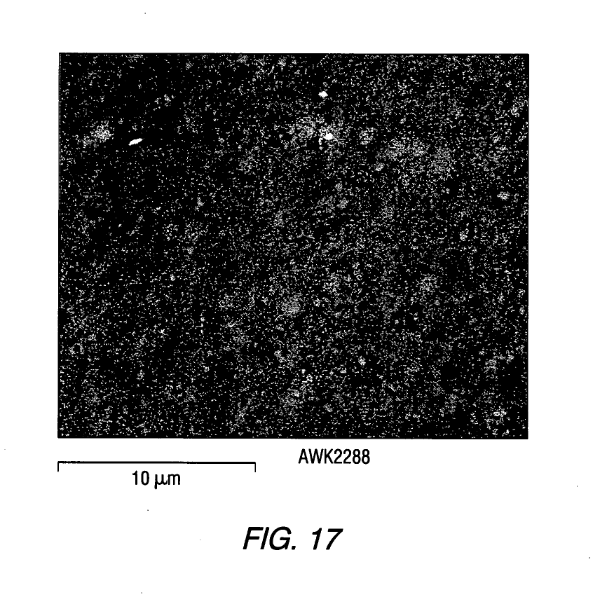

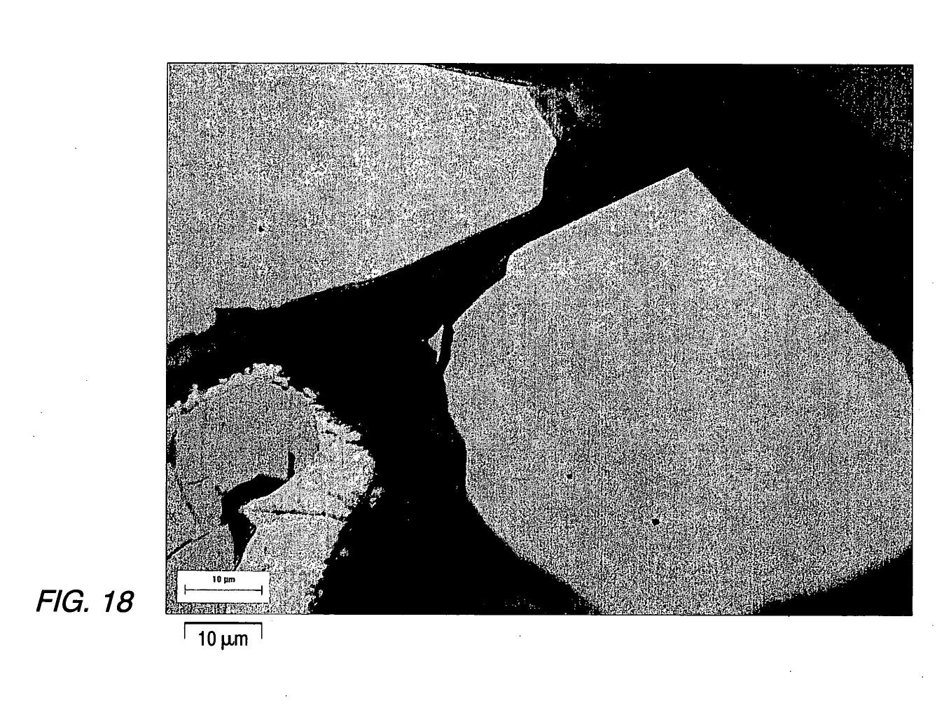

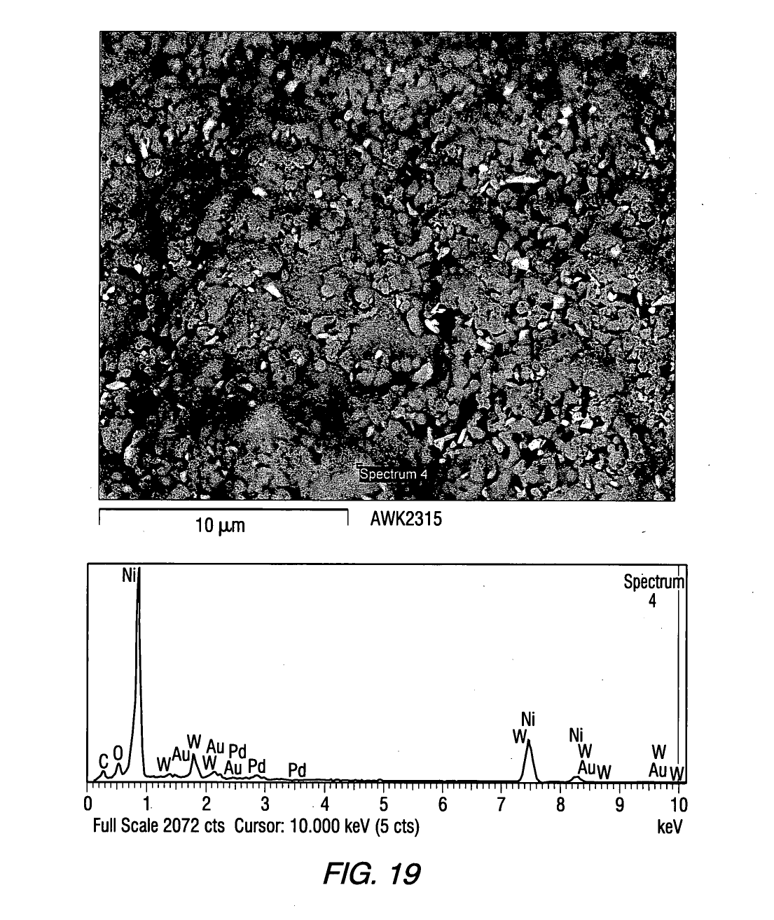

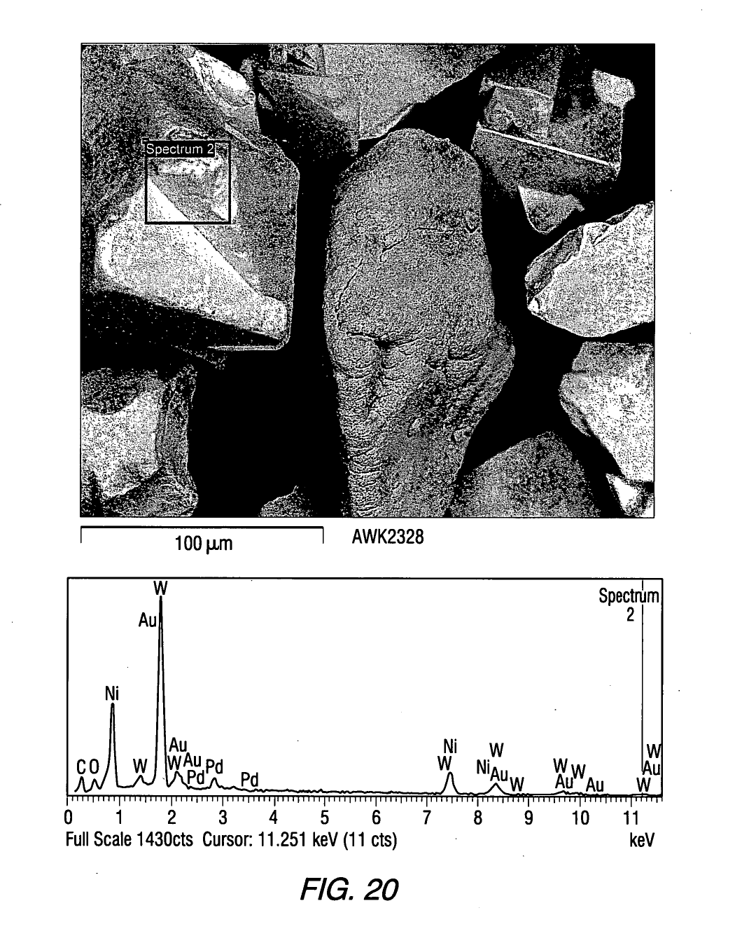

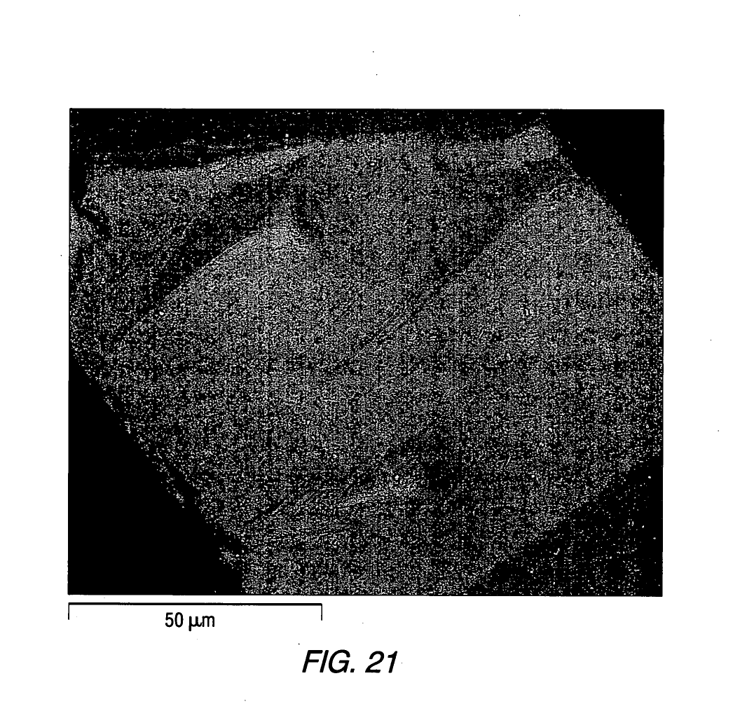

Photomicrographs and corresponding spectrum images of the above-noted Sample Nos. 1, 3, 5 and 6 are shown in FIGS. 14-21. FIGS. 14-16 correspond to Sample No. 1. FIGS. 17 and 18 correspond to Sample No. 3. FIG. 19 corresponds to Sample No. 5. FIGS. 20 and 21 correspond to Sample No. 6.

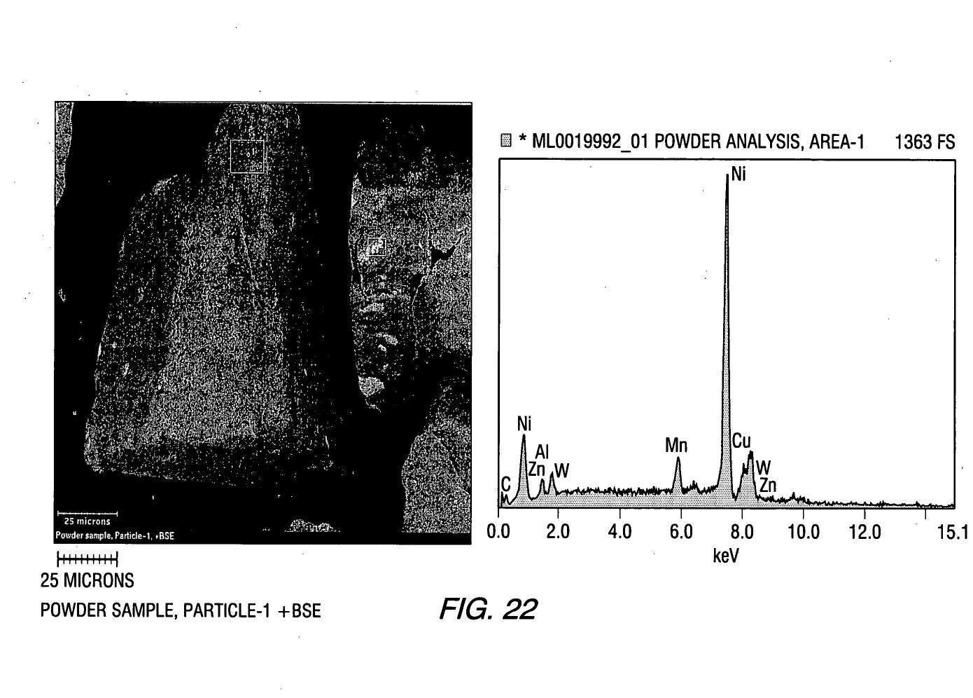

In another example, tungsten carbide particles were first coated with nickel similar to Sample No. 4 above, followed by a second bronze coating, to produce a two-layer coating. A photomicrograph of the resultant bronze and nickel coated tungsten carbide powders and corresponding x-ray diffraction pattern are shown in FIG. 22.

In accordance with embodiments of the present invention, the DVD-fluidized bed derived coating layers may be higher in purity and layer uniformity than comparable CVD coatings. For example, nickel coatings made via the CVD process contain a variable amount of carbon since the nickel precursor from which the coating is generated contains also carbon. In contrast, nickel coatings that are deposited via DVD do not contain such carbon due to the lack of carbon or other impurities in the coating material vapor.

Furthermore, the use of physical vapor deposition in combination with fluidized bed technology provides several advantages. The present method extends the range of non-line-of-sight-applications that can be coated with a PVD method to the area of particulates such as powders, fibers and whiskers. Particulate surfaces can be coated with materials that could not be coated with CVD-based technologies in one process step such as metal alloys. Particulate surfaces can be coated without the use of hazardous, unstable and/or expensive coating precursors. For example, cobalt coatings can be obtained directly from a cobalt rod rather than the decomposition of cobalt carbonyl, which is hazardous. The DVD-fluidized bed derived coating may comprise multiple layers and/or functionally graded materials such as bronze and nickel coated WC. The DVD-fluidized bed derived coating layers are less susceptible to edge effects than comparable CVD based coatings. The DVD-fluidized bed derived coating layers are more economical to deposit than comparable CVD based coatings. The DVD-fluidized bed combination allows for high coating material utilization efficiencies. Typically, efficiencies greater than 15% or higher are achieved. The DVD-fluidized bed combination allows for very high solid flux through the reactor providing strong economies of scale. Applying fluidized beds in general and recirculating fluidized beds in particular in combination with DVD allows for controlled and steady flow through out the operation. Operation is further facilitated since designs can be employed that minimize the need for mechanical parts.

Whereas particular embodiments of this invention have been described above for purposes of illustration, it will be evident to those skilled in the art that numerous variations of the details of the present invention may be made without departing from the invention as defined in the appended claims.

1. A method of coating particulates by physical vapor deposition, the method comprising:
generating a vapor containing a coating material in a vacuum;
suspending the particulates to be coated in a fluidization gas; and
physically depositing the vapor on the suspended particulates in the fluidization gas to at least partially coat the particulates with the coating material.

2. The method of claim 1, wherein the vacuum is maintained at a pressure below 10 Torr.

3. The method of claim 1, wherein the vacuum is maintained at a pressure between 10⁻⁴ and 1 Torr.

4. The method of claim 1, further comprising directing an electron beam at a target material to generate the coating material vapor.

5. The method of claim 4, wherein the target material comprises at least one substantially pure metal, metal alloy, intermetallic, ceramic, amorphous material, glass, clay and/or carbonaceous material.

6. The method of claim 4, further comprising directing the electron beam at multiple targets.

7. The method of claim 6, wherein the multiple targets comprise different materials.

8. The method of claim 1, wherein the coating material vapor comprises atoms and/or ions of the coating material.

9. The method of claim 1, wherein the step of physically depositing the coating material vapor is conducted in a fluidized bed reactor containing the particulates suspended in the fluidization gas.

10. The method of claim 9, wherein the fluidization gas is exhausted from the fluidized bed reactor separately from the coated particulates.

11. The method of claim 9, wherein the vapor containing the coating material is generated in a separate location from the fluidized bed reactor.

12. The method of claim 9, wherein the vapor containing the coating material is generated in the fluidized bed reactor.

13. The method of claim 9, wherein the fluidized bed reactor comprises a recirculating fluidized bed.

14. The method of claim 9, wherein the fluidized bed reactor comprises a non-recirculating fluidized bed.

15. The method of claim 9, wherein the particles are preheated in the fluidized bed prior to the introduction of the coating material vapor.

16. The method of claim 15, wherein the particles are preheated at temperatures of from 20° C. to 1,000° C.

17. The method of claim 1, wherein the particulates comprise powders, fibers, unwoven fibers, chopped fibers, milled fibers, whiskers, nanosized materials, dendrimers, pigments and/or amorphous materials.

18. The method of claim 1, wherein the particulates comprise elements, metals, metal alloys, intermetallics, ceramics, oxides, carbides, borides, nitrides, carbonitrides, plastics and/or woods.

19. The method of claim 1, wherein the particulates comprise tungsten carbide, ductile iron, steel, stainless steel, clay, seacoal, graphite, alumina, glass and/or mullite.

20. The method of claim 1, wherein the particulates comprise metals selected from nickel, iron, steel, stainless steel, aluminum, gold, silver and/or tungsten.

21. The method of claim 1, wherein the particulates comprise oxides selected from titania and/or alumina.

22. The method of claim 1, wherein the particulates comprise carbides selected from tungsten carbide, boron carbide and/or titanium carbide.

23. The method of claim 1, wherein the particulates have an average size of from 1 nm to 10 mm.

24. The method of claim 1, wherein the particulates have an average size of from 5 nm to 1 mm.

25. The method of claim 1, wherein the coating material comprises a plurality of materials.

26. The method of claim 1, wherein the coating material is functionally graded.

27. The method of claim 1, wherein the coating material fully coats the particulates.

28. The method of claim 1, wherein the coating material partially coats the particulates.

29. The method of claim 1, wherein the coating has a thickness of from 1 nm to 1 mm.

30. The method of claim 1, wherein the coating has a thickness of from 10 nm to 100 microns.

31. The method of claim 1, wherein the coating has a controlled orientation.

32. An apparatus for coating particulates comprising:
means for generating a vapor containing a coating material in a vacuum;
means for suspending the particulates to be coated in a fluidization gas; and
means for physically depositing the vapor on the suspended particulates in the fluidization gas to at least partially coat the particulates with the coating material.

33. An apparatus for coating particulates comprising:
a source of vaporized coating material; and
a fluidized bed containing the particulates to be coated suspended in a fluidization gas, wherein the vaporized coating material is physically deposited on the suspended particulates in the fluidized bed.
